(19) United States
(12) Patent Application Publication
(10) Pub. No.: US 2026/0237651 A1
(43) Pub. Date: Aug. 13, 2026

(54) HIGH-ENTROPY SINGLE CRYSTAL STRUCTURED CATHODE MATERIAL WITH A GRADIENT ELEMENT DISTRUBUTION

(71) Applicant: GM Global Technology Operations LLC, Detroit, MI (US)

(72) Inventors: Jingyuan Liu, Shanghai (CN); Xin Zhang, Shanghai (CN); Haijing Liu, Shanghai (CN); Peiyu Hou, Jinan City (CN); Maosheng Gong, Jinan City (CN)

(21) Appl. No.: 19/062,653

(22) Filed: Feb. 25, 2025

(30) Foreign Application Priority Data
Feb. 11, 2025 (CN) 202510154583.1

(51) Int. Cl. H01M 4/525; H01M 4/02; H01M 4/131; H01M 4/36; H01M 4/505

(52) U.S. Cl. CPC H01M 4/525; H01M 4/131; H01M 4/366; H01M 4/505; H01M 2004/021; H01M 2004/028; H01M 2220/20

(57) ABSTRACT

A vehicle battery cell, a battery for an electric vehicle, and a cathode for a vehicle battery cell is provided. The vehicle battery cell includes a cathode current collector and a cathode disposed on a surface of the cathode current collector. The cathode includes a high-entropy (HE) single crystal-structure material absent of voids or cracks and at least one doping element disposed within each single crystal particle of the material. The material includes at least one of nickel cobalt manganese (NCM), nickel cobalt aluminum (NCA), nickel manganese (NMₓ), or nickel cobalt manganese aluminum (NCMA), and a particle size of the high-entropy (HE) single crystal-structure material is greater than 1 micrometer (μm). A concentration of the at least one doping element increases radially from a center to the surface, and a concentration of the material decreases radially from the center to the surface.

### INTRODUCTION

The present disclosure relates to a battery cell, and more particularly, to a doped cathode disposed within the battery cell.

Electric and hybrid electric vehicle technology is enabled by the development and deployment of rechargeable, secondary batteries, which provide energy to the vehicle powertrain. Secondary batteries include lithium ion batteries, which generally include a cathode, anode, separator, and electrolyte. The cathode provides a source of lithium ions and determines capacity and average voltage of a battery. The anode stores and releases lithium ions received from the cathode when energy is needed. The separator prevents the cathode and anode from contacting and shorting out the battery, and the electrolyte provides a medium between the cathode and anode through which the lithium ions travel. Energy density of the secondary battery may be increased by adding more cathode and anode active material and increasing the density of the cathode and anode.

Cathode electrodes and anode electrodes are formed by coating current collectors with active cathode material and active anode material, respectively. The coatings often include active materials, a binder, additives, and/or a solvent. At least in the case of cathodes, the active materials disposed on the current collectors are responsible for the electrochemical reactions that store and release energy during battery operation.

Thus, while present battery and cathode chemistries achieve their intended purpose, there is a need for new and improved cathode chemistries that offer improved structural and chemical stability, efficient electronic and ionic conductivities, and better cyclability.

### SUMMARY

According to several aspects of the present disclosure, a vehicle battery cell is provided. The vehicle battery cell includes a cathode current collector and a cathode disposed on a surface of the cathode current collector. The cathode includes a high-entropy (HE) single crystal-structure material absent of voids or cracks and at least one doping element disposed within each single crystal particle of the material. The material includes at least one of nickel cobalt manganese (NCM), nickel cobalt aluminum (NCA), nickel manganese (NMₓ), or nickel cobalt manganese aluminum (NCMA), and a particle size of the high-entropy (HE) single crystal-structure material is greater than 1 micrometer (μm). The concentration of the at least one doping element increases radially from a center to the surface, and a concentration of the material decreases radially from the center to the surface.

In accordance with another aspect of the disclosure, the material includes transition metals including at least one of manganese (Mn), cobalt (Co), nickel (Ni), aluminum (Al), magnesium (Mg), titanium (Ti), zirconium (Zr), molybdenum (Mo), or niobium (Nb).

In accordance with another aspect of the disclosure, the material includes transition metals having a fraction of nickel in all the transition metals between 0.5 and 0.95.

In accordance with another aspect of the disclosure, the material has a formula LiNi_{0.8}Mn_{0.08}Co_{0.05}Ti_{0.02}Mg_{0.02}Nb_{0.01}Mo_{0.02}Zr_{0.05}O₂.

In accordance with another aspect of the disclosure, the at least one doping element includes at least one of aluminum (Al), magnesium (Mg), titanium (Ti), zirconium (Zr), molybdenum (Mo), or niobium (Nb).

In accordance with another aspect of the disclosure, a maximum concentration of the at least one doping element on or at the surface is less than 10% by weight.

In accordance with another aspect of the disclosure, a minimum concentration of the at least one doping element in the center is greater than 1% by weight.

In accordance with another aspect of the disclosure, a coating is disposed on the surface of each single crystal particle of the material.

In accordance with another aspect of the disclosure, the coating is a single layer.

In accordance with another aspect of the disclosure, the coating includes at least two layers.

In accordance with another aspect of the disclosure, the coating is continuous and covers the surface entirely.

In accordance with another aspect of the disclosure, the coating is discontinuous and covers only a portion of the surface.

In accordance with another aspect of the disclosure, the coating includes an island-type configuration.

In accordance with another aspect of the disclosure, the coating has a thickness between 10 nanometers (nm) and 1 micrometer (μm).

In accordance with another aspect of the disclosure, the coating is a composite coating including at least one of aluminum oxide (Al₂O₃), zirconium dioxide (ZrO₂), magnesium oxide (MgO), lithium aluminum titanium phosphate (LATP), or lithium niobate (LiNbO₂).

According to several aspects of the present disclosure, a battery for an electric vehicle is provided. The battery includes a battery cell, which further includes a cathode current collector, a cathode disposed on a surface of the cathode current collector, an anode disposed on an anode current collector, a separator positioned between the cathode and the anode, and an electrolyte configured for carrying ions between the cathode and the anode. The cathode includes a high-entropy (HE) single crystal-structure material absent of voids or cracks and at least one doping element disposed within each single crystal particle of the material. The material includes at least one of nickel cobalt manganese (NCM), nickel cobalt aluminum (NCA), nickel manganese (NMₓ), or nickel cobalt manganese aluminum (NCMA), and a particle size of the high-entropy (HE) single crystal-structure material is greater than 1 micrometer (μm). The concentration of the at least one doping element increases radially from a center to the surface, and a concentration of the material decreases radially from the center to the surface.

In accordance with another aspect of the disclosure, the material has a formula LiNi_{0.8}Mn_{0.08}Co_{0.05}Ti_{0.02}Mg_{0.02}Nb_{0.01}Mo_{0.02}Zr_{0.05}O₂.

In accordance with another aspect of the disclosure, the at least one doping element includes at least one of aluminum (Al), magnesium (Mg), titanium (Ti), zirconium (Zr), molybdenum (Mo), or niobium (Nb).

In accordance with another aspect of the disclosure, a coating is disposed on the surface of each single crystal particle of the material.

According to several aspects of the present disclosure, a cathode for a vehicle battery cell is provided. The cathode includes a cathode current collector and a cathode disposed on a surface of the cathode current collector. The cathode includes a high-entropy (HE) single crystal-structure material absent of voids or cracks, at least one doping element disposed within each single crystal particle of the material, and a coating disposed on the surface of each single crystal particle of the material having a thickness between 20 nanometers (nm) and 50 nanometers (nm). The material includes at least one of nickel cobalt manganese (NCM), nickel cobalt aluminum (NCA), nickel manganese (NMₓ), or nickel cobalt manganese aluminum (NCMA). A particle size of the high-entropy (HE) single crystal-structure material is greater than 1 micrometer (μm). The at least one doping element includes at least one of aluminum (Al), magnesium (Mg), titanium (Ti), zirconium (Zr), molybdenum (Mo), or niobium (Nb). A concentration of the at least one doping element increases radially from a center to the surface, and a concentration of the material decreases radially from the center to the surface.

The above features and advantages, and other features and advantages, of the presently disclosed system and method are readily apparent from the detailed description, including the claims, and examples when taken in connection with the accompanying drawings.

### BRIEF DESCRIPTION OF THE DRAWINGS

The present disclosure will become more fully understood from the detailed description and the accompanying drawings, wherein:

FIG. 1 is a perspective view illustrating an example of a vehicle having an electric motor powered by a battery pack with a high-entropy cathode, in accordance with the present disclosure.

FIG. 2 is a cross section schematic view of a battery cell in the battery pack in the vehicle shown in FIG. 1, where the battery cell includes a high-entropy cathode, in accordance with the present disclosure.

FIG. 3 is a perspective view illustrating a high-entropy single crystal of the cathode for the battery cell shown in FIG. 2, where the single crystal has a gradient element distribution, in accordance with the present disclosure.

FIG. 4 is a perspective view illustrating a high-entropy single crystal of the cathode for the battery cell shown in FIG. 2, where the single crystal has a single layer continuous coating, in accordance with the present disclosure.

FIG. 5 is a perspective view illustrating a high-entropy single crystal of the cathode for the battery cell shown in FIG. 2, where the single crystal has multiple layer continuous coating, in accordance with the present disclosure.

FIG. 6 is a perspective view illustrating a high-entropy single crystal of the cathode for the battery cell shown in FIG. 2, where the single crystal has a discontinuous coating, in accordance with the present disclosure.

FIG. 7 is a perspective view illustrating a high-entropy single crystal of the cathode for the battery cell shown in FIG. 2, where the single crystal has a single material island-type coating, in accordance with the present disclosure.

FIG. 8 is a perspective view illustrating a high-entropy single crystal of the cathode for the battery cell shown in FIG. 2, where the single crystal has a multiple material island-type coating, in accordance with the present disclosure.

### DETAILED DESCRIPTION

The following description is merely exemplary in nature and is not intended to limit the present disclosure, application, or uses. Furthermore, there is no intention to be bound by any expressed or implied theory presented in the preceding introduction, summary, or the following detailed description. It should be understood that throughout the drawings, corresponding reference numerals indicate like or corresponding parts and features.

Reference will now be made in detail to several examples of the disclosure that are illustrated in accompanying drawings. Whenever possible, the same or similar reference numerals are used in the drawings and the description to refer to the same or like parts or steps. The drawings are in simplified form and are not to precise scale. The following description is merely exemplary in nature and is not intended to limit the present disclosure, application, or uses.

A high-entropy (HE) single crystal-structured nickel cobalt manganese (NCM)/nickel cobalt manganese (NCA)-based cathode active material with a gradient element distribution is disclosed herein. A primary issue is structural and chemical stability of cathode active materials during repeated charge and discharge cycles. Degradation of the cathode leads to reduced capacity, lower efficiency, and shorter battery life. A cathode must be optimized to ensure efficient electron transport and minimize energy losses.

High entropy NCM/NCA materials are promising for cathode use because of improved cycling stability and food thermal stability. However, doping material is costly, and single crystal high entropy material is challenging to synthesize. The NCM/NCA materials with high nickel content suffer from an unstable structure. During cycling, a layered structure of NCM/NCA can be distorted and can lead to capacity fading. Under elevated temperatures, the layered structure decomposes and releases oxygen, which may further cause thermal runaway. The cathode material disclosed herein with a single crystal structure and a high entropy component along with gradient doping overcomes these challenges.

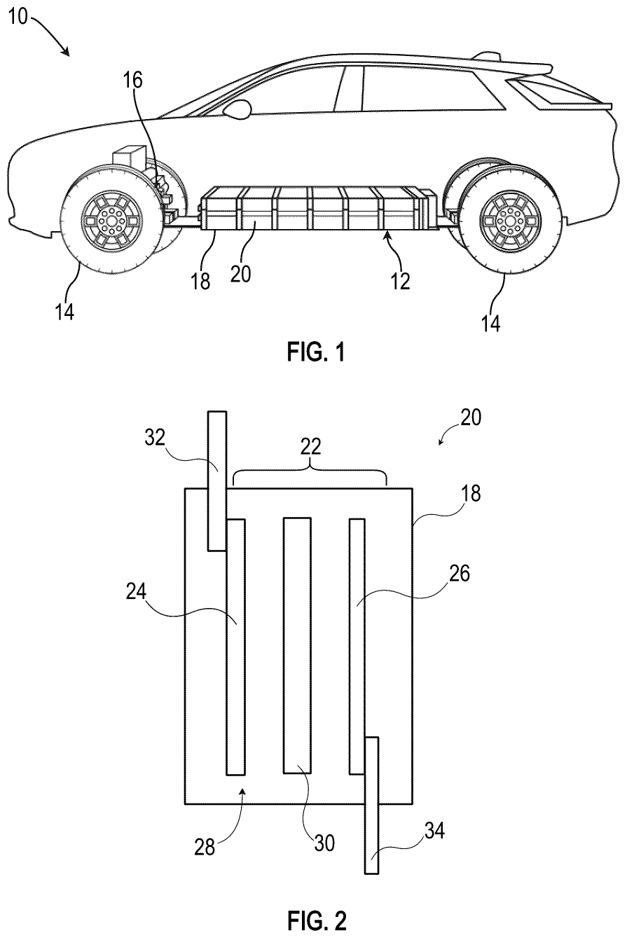

Referring to FIG. 1, a perspective view of a vehicle 10 having a battery pack 12 is illustrated, in accordance with the present disclosure. The battery pack 12 is illustrated with an exemplary vehicle 10. The vehicle 10 is an electric vehicle or hybrid vehicle having wheels 14 driven by at least one electric motor/inverter 16. The electric motors/inverters 16 receive power from the battery pack 12. While the vehicle 10 is illustrated as a passenger road vehicle, it should be appreciated that the battery pack 12 may be used with various other types of vehicles. For example, the battery pack 12 may be used in nautical vehicles, such as boats, or aeronautical vehicles, such as drones or passenger airplanes. Moreover, the battery pack 12 may be used as a stationary power source separate and independent from a vehicle. The battery pack 12 includes a housing 18 for carrying and supporting a plurality of battery cells 20. In an example, the battery pack 12 may have fifty or more battery cells 20.

As used herein, the term “vehicle” is not limited to automobiles. While the present technology is described primarily herein in connection with electric and hybrid-electric vehicles, the technology is not limited to electric and hybrid-electric vehicles. The concepts can be used in a wide variety of applications, such as in connection with components used in motorcycles, mopeds, locomotives, aircraft, marine craft, and other vehicles, as well as in other applications utilizing batteries, such as in portable power stations, such as those used for powering remote job sites, emergency back-up power supplies, and permanent power stations associated with buildings and equipment, all of which may be powered by, for example, solar or wind-powered generator systems, power mains, and fuel based power generators such as gasoline, propane, kerosene, or diesel generators as well as sterling engines.

FIG. 2 illustrates one battery cell 20 within the battery pack 12 illustrated in FIG. 1. The battery pack 12 and the battery cells 20 are understood to be rechargeable batteries that may be discharged upon application of a load and recharged upon the application of an external power source. The battery cells 20 may be, for example, pouch-style or prismatic cells. Alternatively, the battery cells 20 may be cylindrical-style cells.

Each battery cell 20 disposed within the battery pack 12 shown in FIG. 1 has at least one electrode stack 22, which further includes a cathode 24, an anode 26, an electrolyte 28, and/or a separator 30. Each battery cell 20 may have tens or hundreds of electrode stacks 22. Each electrode stack 22 is connected to a cathode current collector 32 and an anode current collector 34. The electrode stacks are placed in the housing 18, which are filled with the electrolyte 28. The electrolyte 28 transports ions between the cathode 24 and the anode 26. The cathode current collector 32 and the anode current collector 34 are thin metal plates or foils disposed on sides of the electrode stacks 22 and/or housing 18 and typically have a thickness between 0.1 and 1 millimeter. The cathode current collector 32 and the anode current collector 34 may be made of copper or aluminum and are attached to the electrode stacks 22 to transmit the electric current to an external circuit (not shown).

During discharge, when a load is applied to the battery cells 20, Li+ ions move from the anode 26 to the cathode 24 through the separator 30 by way of the electrolyte 28. Equivalent electrons e⁻move through battery circuitry from the cathode 24 to the anode 26, providing energy to a battery load. While charging and upon application of an external voltage, Li⁺ ions move from the cathode 24 to the anode 26 by way of the electrolyte 28 through the separator 30 and may be intercalated into the anode 26.

Each battery cell 20, such as that illustrated in FIG. 2, generally includes a cathode current collector 32, a cathode 24 disposed on the cathode current collector 32, an anode current collector 34, an anode 26 disposed on the anode current collector 34, a separator 30 positioned between the cathode 24 and anode 26, and an electrolyte 28. While the illustrated battery cells 20 include one anode 26 (and anode current collector 34) and one cathode (and one cathode current collector 32), the battery cell 20 may alternatively include two or more cathodes 24 (and cathode current collectors 32) and one or more anodes 26 (and anode current collectors 34). In further alternative embodiments, the battery cell 20 may include or one or more cathodes 24 (and cathode current collectors 32) and two or more anodes 26 (and anode current collectors 34). In any of the designs above, one or more separators 30 are interleaved between the cathodes 24 and anodes 26 to prevent the cathodes 24 and the anodes 26 from contacting.

In the various styles of battery cells 20 noted above, the cathode current collector 32 and anode current collector 34 are formed from conductive materials. In embodiments, the cathode current collector 32 includes aluminum. Alternatively, or additionally, the cathode current collector 32 may include copper clad aluminum, stainless steel, and/or other suitable materials. The anode current collector 34 may include one or more of copper, nickel, stainless steel, and titanium. The cathode current collector 32 and the anode current collector 34 are illustrated as being in the form of a foil; however, it will be appreciated that other forms may be exhibited such as mesh or a composite-type material. The cathode current collector 32 may exhibit a thickness in the range of 5 micrometers to 50 micrometers including all values and ranges therein, such as in the range of 5 micrometers to 25 micrometers. The anode current collector 34 exhibits a thickness in the range of 4 micrometers to 50 micrometers including all values and ranges therein, such as in the range of 4 micrometers to 25 micrometers, or a specific example of 13 micrometers.

The cathode 24 includes a cathode active material configured to provide a source of lithium ions (Li⁺) and undergo reversible insertion or intercalation of lithium ions determining, for example, the capacity and average voltage of a battery. The cathode active material includes a high-entropy (HE) single crystal-structure material absent of voids or cracks. A high-entropy (HE) single crystal-structure material can include, for example, an alloy or material formed by mixing five or more elements in roughly equal proportions resulting in a high configurational entropy that stabilizes the material structure. A high-entropy (HE) single crystal-structure material is configured to have exceptional strength, durability, and resistance to corrosion and oxidation.

The cathode active material includes at least one of nickel cobalt manganese (NCM), nickel cobalt aluminum (NCA), nickel manganese (NMₓ), or nickel cobalt manganese aluminum (NCMA). In one example, the cathode active material has a formula LiNi_{0.8}Mn_{0.08}Co_{0.05}Ti_{0.02}Mg_{0.02}Nb_{0.01}Mo_{0.02}Zr_{0.05}O₂. In one example, the cathode active material and the high-entropy (HE) single crystal-structure material is greater than 1 micrometer (μm) (e.g., an average diameter, thickness). It will be appreciated that the cathode active material and the high-entropy (HE) single crystal-structure material may include other configurations, sizes, and/or shapes.

Additionally, the cathode 24 and the cathode active material may include one or more transition metals. For example, the transition metals may include at least one of manganese (Mn), cobalt (Co), nickel (Ni), aluminum (Al), magnesium (Mg), titanium (Ti), zirconium (Zr), molybdenum (Mo), or niobium (Nb). In one example, the cathode active material includes transition metals where a fraction of nickel in all the transition metals is between 0.5 and 0.95 (e.g., between 50% and 95% by molar ratio).

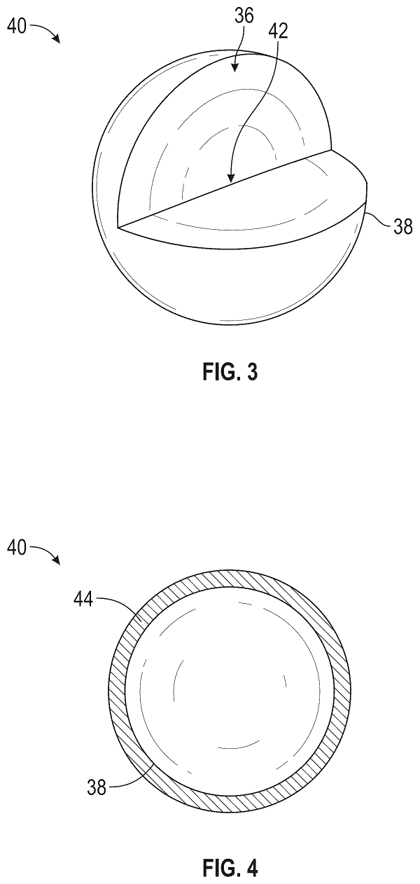

The cathode 24 includes at least one doping element 36 disposed on or within a surface 38 of each single crystal particle 40 of the cathode 24 and cathode active material, as shown in FIG. 3. The doping elements are introduced into the cathode active material to enhance performance. For example, the transition metals can be used as doping elements to improve the structural stability and electrochemical performance of the cathode 24. Doping with lithium can assist in stabilizing the crystal structure and improving the overall capacity of the battery cell 20. Magnesium doping can be used to enhance ionic conductivity and structural integrity of the cathode 24, and niobium doping can improve rate capability and cycling stability of the cathode 24.

As illustrated in FIG. 3, a concentration of doping element concentration is a gradient concentration and increases radially from a center 42 to the surface 38 of each single crystal particle of the cathode active material and the cathode 24. In this case, the doping element concentration of the cathode active material increases radially from the center 42 to the surface 38. In an example, a maximum concentration of the doping elements on or at the surface 38 is less than 10% by weight (wt.). In a further example, a minimum concentration of the doping elements in the center 42 is greater than 1% wt.

FIG. 4 illustrates a coating 44 disposed on the surface 38 of each single crystal particle 40 of the active cathode material. The coating 44 may be used to protect the active cathode material from corrosion and may enhance performance of the cathode 24. The coating 44 may also function to increase energy density and/or reduce battery size and weight. The coating 44 may be a composite coating including at least one of aluminum oxide (Al₂O₃), zirconium dioxide (ZrO₂), magnesium oxide (MgO), lithium aluminum titanium phosphate (LATP), or lithium niobate (LiNbO₂). It will be appreciated that the coating 44 may include other appropriate materials that prevent corrosion and/or enhance battery performance. In the example shown in FIG. 4, the coating 44 extends continuously over an entire surface of each single crystal particle 40 of the active cathode material. A continuous coating 44 may include a thickness ranging from 10 nanometers (nm) to 1 micrometer (μm). In one example, the thickness of the coating 44 is between 20 nm and 50 nm.

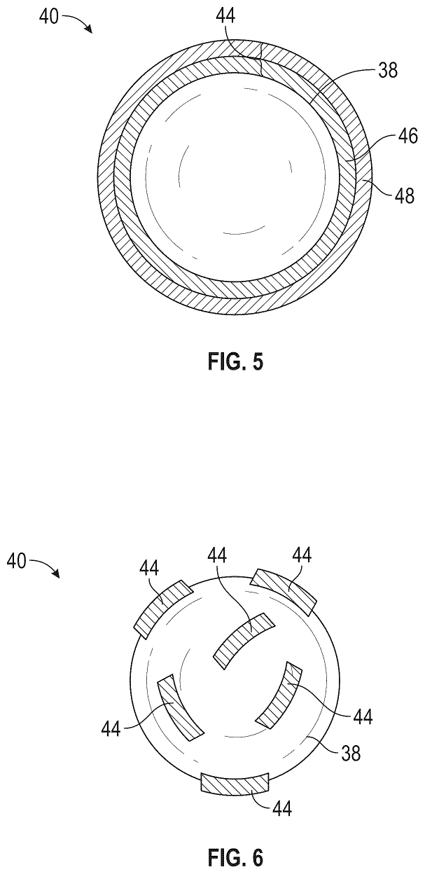

In the embodiment depicted in FIG. 5, the coating 44 includes a multiple layer (e.g., two layers) configuration on the surface 38 of each single crystal particle 40 of the active cathode material. In this embodiment, a first coating 46 covers or extends continuously over the entire surface of each single crystal particle 40 of the active cathode material. Additionally, a second coating 48 continuously covers or extends over the entire surface of the first coating 46. The first coating 46 and the second coating 48 function to prevent corrosion and/or enhance performance of the cathode 24 and the vehicle battery cell 20.

FIG. 6 illustrates an example of the coating 44, where the coating 44 is discontinuous over the surface of the single crystal particle 40 of the active cathode material. In this example, the discontinuous coating 44 facilitates a portion of the surface being exposed to an electrolyte within the vehicle battery cell 20 and a portion of the surface 38 protected from exposure to the electrolyte. A discontinuous coating 44 may include a thickness ranging from 10 nanometers (nm) to 1 micrometer (μm). In one example, the thickness of the coating 44 is between 20 nm and 50 nm. Additionally, the discontinuous coating 44 may coat the surface 38 between 50% and 90% of the surface area. In an example, the discontinuous coating 44 coats the surface 38 between 50% and 70% of the surface area.

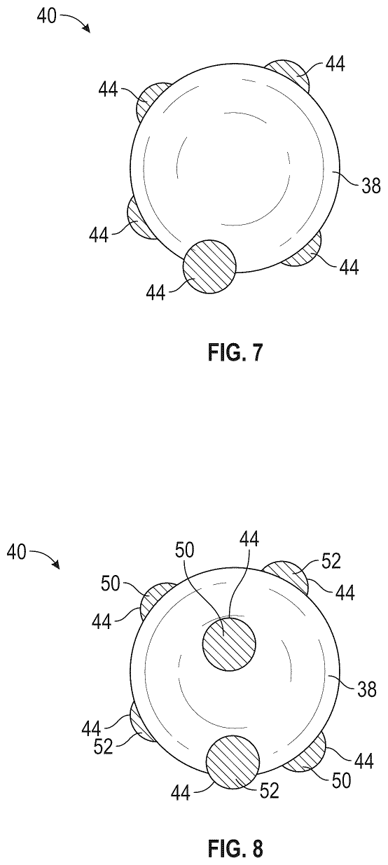

FIG. 7 illustrates an example of a discontinuous coating 44 in an island-type configuration. In this configuration, the coating 44 may be dispersed in portions or islands over the surface 38 of the single crystal particle 40. Each portion or island of the coating 44 may be spherical or partially spherical in shape. The islands shown in FIG. 7 are formed of a single material.

FIG. 8 illustrates an example of a discontinuous coating 44 in an island-type configuration. In this configuration, the coating 44 includes a first material 50 and a second material 52, which may be dispersed in portions or islands over the surface 38 of the single crystal particle 40. Each portion or island of the coating 44 may be spherical or partially spherical in shape. While the islands shown in FIG. 7 are formed of two materials, it will be appreciated that the islands may be formed from more than two materials (e.g., three materials, four materials, and so forth).

Referring again to FIG. 2, the anode 26 includes materials that undergo reversible insertion or intercalation of lithium ions at a lower electrochemical potential than the cathode 24 material such that an electrochemical potential difference exists between the anode 26 and cathode 24. The anode 26 may include one or more of lithium metal; alloys of lithium for example lithium silicon alloy, lithium aluminum alloy, lithium indium alloy, lithium titanate, and lithium tin alloy; carbon based materials for example graphite, activated carbon, carbon black and graphene; silicon; silicon based alloys; silicon oxide; silicon based composite materials; tin oxide; aluminum; indium; zinc; germanium; and titanium oxide; as well as any combination of the above. In embodiments, the anode 26 may exhibit a thickness in the range of 50 micrometers to 150 micrometers including all values and ranges therein. A combined anode 26 and anode current collector 34 provide an anode electrode.

As shown in FIG. 2, the separator 30 is a porous material formed of an electrically insulative material that prevents the cathode 24 and the anode 26 from contacting and potentially shorting out the battery circuit. The separator 30 is sandwiched, or at least partially enclosed, between the cathode 24 and anode 26 allowing the passage of the lithium ions and electrolyte 28 through the pores of the separator 30. The separator 30 may include one or more of a composite material, a polymeric material, or a non-woven material. In embodiments, the separator 30 includes at least one of polyethylene, polypropylene, polyamide, polytetrafluoroethylene, polyvinylidene fluoride, and polyvinyl chloride. Additionally, the separator 30 may be filled, i.e., include fillers dispersed therein, wherein the filler includes a material such as glass fiber. In additional or alternative embodiments, the separator 30 may include at least one of a thermally stable, porous polymer coating and a ceramic coating such as an alumina coating. The coating is disposed on one or more surfaces of a porous polymer film, the polymer film being selected from at least one of polyethylene and polypropylene. The separator 30 may include one or more layers, wherein each layer is formed from one or more of the materials noted above. The separator 30 may take the form of film or a mesh, such as woven mesh or a slit film. In embodiments, the separator 30 exhibits a thickness in the range of 4 micrometers to 25 micrometers, including all values and ranges therein.

Still referring to FIG. 2, the electrolyte 28 provides a medium between the cathode 24 and anode 26 through which lithium ions travel. The medium may be a liquid, gel, or solid, and is capable of conducting the lithium ions between the cathode 24 and the anode 26. The electrolyte 28 permeates the pores of the porous separator 30 and wets or otherwise contacts the surfaces of the cathode 24 and anode 26 as well as the separator 30. In embodiments, the electrolyte 28 includes one or more lithium salts dissolved in non-aqueous organic solvent. Some example of lithium salts may include one or more of lithium hexafluorophosphate (LiPF6), lithium perchlorate (LiClO4), lithium tetrachloroaluminate (LiAlCl₄), lithium iodide (LiI), lithium bromide (LiBr), lithium thiocyanate (LiSCN), lithium tetrafluoroborate (LiBF₄), lithium tetraphenylborate (LiB(C₆H₅)₄), lithium bis(oxalato)borate (LiB(C₂O₄)₂) (LiBOB), lithium difluorooxalatoborate (LiBF₂(C₂O₄)), lithium hexafluoroarsenate (LiAsF₆), lithium trifluoromethanesulfonate (LiCF₃SO₃), lithium bis(trifluoromethane)sulfonylimide (LiN(CF₃SO₂)₂), lithium bis(fluorosulfonyl) imide (LiN(F_{S}O₂)₂) (LiSFI), lithium (triethylene glycol dimethy 1 ether)bis(trifluoromethanesulfonyl)imide (Li(G₃)(TFSI), and/or lithium bis(trifluoromethanesulfonyl)azanide (LiTFSA). The lithium salt may be present in the electrolyte 28 at a concentration (moles (M) of salt per liter of solvent) ranging from 1 M to 4 M, including all values and ranges therein, for example 2 M or 3 M.

The non-aqueous aprotic organic solvent includes or more of various alkyl carbonates, for example cyclic carbonates (e.g., ethylene carbonate (EC), propylene carbonate (PC), butylene carbonate (BC), fluoroethylene carbonate (FEC)), linear carbonates (e.g., dimethyl carbonate (DMC), diethyl carbonate (DEC), ethylmethylcarbonate (EMC)), aliphatic carboxylic esters (e.g., methyl formate, methyl acetate, methyl propionate), γ-lactones (e.g., γ-butyrolactone, γ-valerolactone), chain structure ethers (e.g., 1,2-dimethoxyethane, 1-2-diethoxyethane, ethoxymethoxy ethane), and/or cyclic ethers (e.g., tetrahydrofuran, 2-methyltetrahydrofuran) , 1,3-dioxolane).

The vehicle battery cell 20 and battery pack 12 for the vehicle 10 of the present disclosure is advantageous and beneficial over prior art. The cathode 24 and active cathode material with a single crystal structure and a high entropy component along with gradient doping overcomes the challenges of conventional cathodes. The high entropy structure facilitates stabilization of the high nickel content NCM/NCA structure. Additionally, the doping elements are concentrated in the surface and reduced near the center of each single crystal structure, which use the minimum amount of doping elements and provide enhanced cycling life and improved safety properties. Further, the high entropy structure exists internally and protects the single crystal structure even is cracking occurs during cycling.

This description is merely illustrative in nature and is in no way intended to limit the disclosure, its application, or uses. The broad teachings of the disclosure can be implemented in a variety of forms. Therefore, while this disclosure includes particular examples, the true scope of the disclosure should not be so limited since other modifications will become apparent upon a study of the drawings, the specification, and the following claims.

What is claimed is:

1. A vehicle battery cell, comprising:
a cathode current collector; and
a cathode disposed on a surface of the cathode current collector, wherein the cathode includes
a high-entropy (HE) single crystal-structure material absent of voids or cracks, wherein the material includes at least one of nickel cobalt manganese (NCM), nickel cobalt aluminum (NCA), nickel manganese (NMₓ), or nickel cobalt manganese aluminum (NCMA), and wherein a particle size of the high-entropy (HE) single crystal-structure material is greater than 1 micrometer (μm); and
at least one doping element disposed within each single crystal particle of the material, wherein a concentration of the at least one doping element increases radially from a center to the surface, and wherein a concentration of the material decreases radially from the center to the surface.

2. The vehicle battery cell of claim 1, wherein the material includes transition metals including at least one of manganese (Mn), cobalt (Co), nickel (Ni), aluminum (Al), magnesium (Mg), titanium (Ti), zirconium (Zr), molybdenum (Mo), or niobium (Nb).

3. The vehicle battery cell of claim 1, wherein the material includes transition metals having a fraction of nickel in all the transition metals between 0.5 and 0.95.

4. The vehicle battery cell of claim 1, wherein the material has a formula LiNi_{0.8}Mn_{0.08}Co_{0.05}Ti_{0.02}Mg_{0.02}Nb_{0.01}Mo_{0.02}Zr_{0.05}O₂.

5. The vehicle battery cell of claim 1, wherein the at least one doping element includes at least one of aluminum (Al), magnesium (Mg), titanium (Ti), zirconium (Zr), molybdenum (Mo), or niobium (Nb).

6. The vehicle battery cell of claim 1, wherein a maximum concentration of the at least one doping element on or at the surface is less than 10% by weight.

7. The vehicle battery cell of claim 1, wherein a minimum concentration of the at least one doping element in the center is greater than 1% by weight.

8. The vehicle battery cell of claim 1, further comprising: a coating disposed on the surface of each single crystal particle of the material.

9. The vehicle battery cell of claim 8, wherein the coating is a single layer.

10. The vehicle battery cell of claim 8, wherein the coating includes at least two layers.

11. The vehicle battery cell of claim 8, wherein the coating is continuous and covers the surface entirely.

12. The vehicle battery cell of claim 8, wherein the coating is discontinuous and covers only a portion of the surface.

13. The vehicle battery cell of claim 12, wherein the coating includes an island-type configuration.

14. The vehicle battery cell of claim 8, wherein the coating has a thickness between 10 nanometers (nm) and 1 micrometer (μm).

15. The vehicle battery cell of claim 8, wherein the coating is a composite coating including at least one of aluminum oxide (Al₂O₃), zirconium dioxide (ZrO₂), magnesium oxide (MgO), lithium aluminum titanium phosphate (LATP), or lithium niobate (LiNbO₂).

16. A battery for an electric vehicle, comprising:
a battery cell, the battery cell including:
a cathode current collector;
a cathode disposed on a surface of the cathode current collector, wherein the cathode includes
a high-entropy (HE) single crystal-structure material absent of voids or cracks, wherein the material includes at least one of nickel cobalt manganese (NCM), nickel cobalt aluminum (NCA), nickel manganese (NMₓ), or nickel cobalt manganese aluminum (NCMA), and wherein a particle size of the high-entropy (HE) single crystal-structure material is greater than 1 micrometer (μm); and
at least one doping element disposed within each single crystal particle of the material, wherein a concentration of the at least one doping element increases radially from a center to the surface, and wherein a concentration of the material decreases radially from the center to the surface;
an anode disposed on an anode current collector;
a separator positioned between the cathode and the anode; and
an electrolyte configured for carrying ions between the cathode and the anode.

17. The battery for the electric vehicle of claim 16, wherein the material has a formula LiNi_{0.8}Mn_{0.08}Co_{0.05}Ti_{0.02}Mg_{0.02}Nb_{0.01}Mo_{0.02}Zr_{0.05}O₂.

18. The battery for the electric vehicle of claim 16, wherein the at least one doping element includes at least one of aluminum (Al), magnesium (Mg), titanium (Ti), zirconium (Zr), molybdenum (Mo), or niobium (Nb).

19. The battery for the electric vehicle of claim 16, further comprising:
a coating disposed on the surface of each single crystal particle of the material.

20. A cathode for a vehicle battery cell, comprising:
a cathode current collector;
a cathode disposed on a surface of the cathode current collector, wherein the cathode includes
a high-entropy (HE) single crystal-structure material absent of voids or cracks, wherein the material includes at least one of nickel cobalt manganese (NCM), nickel cobalt aluminum (NCA), nickel manganese (NMₓ), or nickel cobalt manganese aluminum (NCMA), and wherein a particle size of the high-entropy (HE) single crystal-structure material is greater than 1 micrometer (μm);
at least one doping element disposed within each single crystal particle of the material, wherein the at least one doping element includes at least one of aluminum (Al), magnesium (Mg), titanium (Ti), zirconium (Zr), molybdenum (Mo), or niobium (Nb), wherein a concentration of the at least one doping element increases radially from a center to the surface, and wherein a concentration of the material decreases radially from the center to the surface; and
a coating disposed on the surface of each single crystal particle of the material having a thickness between 20 nanometers (nm) and 50 nanometers (nm).
